(19) United States
(12) Patent Application Publication
(10) Pub. No.: US 2026/0020210 A1
(43) Pub. Date: Jan. 15, 2026

(54) COMPONENT SUPPLY DEVICE

(71) Applicant: Panasonic Intellectual Property Management Co., Ltd., Osaka (JP)

(72) Inventors: Yoshinori ISOBATA, Fukuoka (JP); Minoru KITANI, Osaka (JP); Hiroaki KATO, Fukuoka (JP); Naoki KARASUDA, Yamanashi (JP); Atuyuki HORIE, Fukuoka (JP); Satoshi KAWAGUCHI, Yamanashi (JP); Kyourei RI, Fukuoka (JP)

(21) Appl. No.: 19/123,096

(22) PCT Filed: Oct. 24, 2023
(86) PCT No.: PCT/JP2023/038397

§ 371 Date: Sep. 22, 2025

(30) Foreign Application Priority Data
Oct. 31, 2022 (JP) 2022-174028

(51) Int. Cl. H05K 13/02; H05K 13/04

(52) U.S. Cl. CPC H05K 13/022; H05K 13/0419

(57) ABSTRACT

A component supply device includes a straightener that straightens a lead part of a cover tape to a state of being directed downstream from a tip of a carrier tape along with movement of the carrier tape that has been sent downstream along a conveyance path and then returned upstream with the lead part leading, and a cover tape peeling part that peels off the cover tape from an upper surface of the carrier tape being sent downstream by catching and drawing the lead part extended downstream from the tip of the carrier tape.

### TECHNICAL FIELD

The present invention relates to a component supply device that exposes a component stored on a carrier tape in a state of being covered with a cover tape, conveys the exposed component to a component extraction position, and supplies the component to a component mounter.

### BACKGROUND ART

Conventionally, there has been known a component supply device that exposes a component stored on a carrier tape in a state of being covered with a cover tape, conveys the exposed component to a component extraction position, and supplies the component to a component mounter. PTL 1 described below discloses such a component supply device having a configuration in which a tip part of a cover tape is projected from a tip of a carrier tape, and the projected part of the cover tape is blown up with air immediately before passing through a component extraction position to be caught and drawn, whereby the cover tape is peeled off from the carrier tape.

### CITATION LIST

### Patent Literature

PTL 1: International Publication No. WO 2021/070954

### SUMMARY OF THE INVENTION

However, the component supply device disclosed in PTL 1 has a problem that when the tip part (lead part) of the cover tape projected from the tip of the carrier tape is bent with respect to the carrier tape, the lead part of the cover tape may be failed to be caught by a cover tape drawing part.

An object of the present invention is to provide a component supply device capable of reliably catching the tip part of the cover tape even when the lead part of the cover tape is bent.

A component supply device of the present invention is a component supply device that peels off a cover tape including a lead part projected from a tip of a carrier tape from the carrier tape, exposes a component stored in the carrier tape in a state of being covered with the cover tape, conveys the component that has been exposed to a component extraction position, and supplies the component to a component mounter. The component supply device includes a conveyance path including a conveyance surface that supports the carrier tape from below, a carrier tape conveyance part that conveys the carrier tape along the conveyance path with the lead part leading, to position the component at a component extraction position, a straightener that is disposed on an upstream side with respect to the component extraction position and straightens the lead part to a state of being directed downstream from the tip of the carrier tape along with movement of the carrier tape that has been sent downstream and then returned upstream by the carrier tape conveyance part, and a cover tape peeling part that is disposed on a downstream side of the straightener and on the upstream side with respect to the component extraction position and peels off the cover tape from an upper surface of the carrier tape being sent downstream by the carrier tape conveyance part by catching and drawing the lead part extended downstream from the tip of the carrier tape.

According to the present invention, even when the lead part of the cover tape is bent, the lead part can be reliably caught by the cover tape drawing part.

### BRIEF DESCRIPTION OF THE DRAWINGS

FIG. 1 is a perspective view of a component mounter with which a tape feeder according to a first exemplary embodiment of the present invention is used.

FIGS. 2(a) and 2(b) are perspective views illustrating the tape feeder according to the first exemplary embodiment of the present invention together with a feeder base of the component mounter.

FIGS. 3(a) and 3(b) are views for describing a case where a lead part of a cover tape of a carrier tape conveyed by the tape feeder according to the first exemplary embodiment of the present invention is a part of the cover tape.

FIGS. 4(a) and 4(b) are views for describing a case where the lead part of the cover tape of the carrier tape conveyed by the tape feeder according to the first exemplary embodiment of the present invention is a part of an auxiliary tape.

FIGS. 5(a) and 5(b) are perspective views of a tape feeder included in the component mounter according to the first exemplary embodiment of the present invention.

FIG. 6 is a side view of the tape feeder according to the first exemplary embodiment of the present invention.

FIG. 7 is a perspective view of a tape cover included in the tape feeder according to the first exemplary embodiment of the present invention.

FIG. 8 is a side view of a part of the tape feeder (when the carrier tape is not conveyed) according to the first exemplary embodiment of the present invention.

FIG. 9 is a side view of the part of the tape feeder (when the carrier tape is conveyed) according to the first exemplary embodiment of the present invention.

FIG. 10 is a perspective view of a state in which the tape cover included in the tape feeder according to the first exemplary embodiment of the present invention is attached to a main body of the tape feeder.

FIG. 11 is a side view illustrating a part of the tape cover included in the tape feeder according to the first exemplary embodiment of the present invention together with a straightener and a cover tape drawing part.

FIG. 12 is a side view of a part of the tape feeder according to the first exemplary embodiment of the present disclosure.

FIG. 13 is a side view of a part of the tape feeder according to the first exemplary embodiment of the present disclosure.

FIG. 14 is a side view of a part of the tape feeder according to the first exemplary embodiment of the present disclosure.

FIG. 15 is a view illustrating a state in which an upward bending of the lead part of the cover tape is straightened by the straightener included in the tape feeder according to the first exemplary embodiment of the present invention.

FIG. 16 is a side view of a part of the tape feeder according to the first exemplary embodiment of the present disclosure.

FIG. 17 is a view illustrating a state in which a downward bending of the lead part of the cover tape is straightened by the straightener included in the tape feeder according to the first exemplary embodiment of the present invention.

FIG. 18 is a side view illustrating a part of the tape cover included in the tape feeder according to the first exemplary embodiment of the present invention together with the straightener and the cover tape drawing part.

FIG. 19 is a side view of a part of the tape feeder according to the first exemplary embodiment of the present disclosure.

FIG. 20 is a side view illustrating a part of the tape cover included in the tape feeder according to the first exemplary embodiment of the present invention together with the cover tape drawing part and the air ejector.

FIG. 21 is a side view illustrating a part of the tape cover included in the tape feeder according to the first exemplary embodiment of the present invention together with the cover tape drawing part and the air ejector.

FIG. 22 is a side view illustrating a part of the tape cover included in the tape feeder according to the first exemplary embodiment of the present invention together with the cover tape drawing part and the air ejector.

FIG. 23 is a side view illustrating a part of the tape cover included in the tape feeder according to the first exemplary embodiment of the present invention together with the cover tape drawing part and the air ejector.

FIG. 24 is a side view of a part of the tape feeder according to the first exemplary embodiment of the present disclosure.

FIG. 25 is a side view of a part of the tape feeder according to the first exemplary embodiment of the present disclosure.

FIG. 26 is a side view illustrating a part of the tape cover included in a tape feeder according to a second exemplary embodiment of the present invention together with a straightener.

FIG. 27 is a side view illustrating a part of the tape cover included in a tape feeder according to a third exemplary embodiment of the present invention together with a straightener.

FIG. 28 is a side view illustrating a part of the tape cover included in a tape feeder according to a fourth exemplary embodiment of the present invention together with a cover tape drawing part, a duct, and a suction part.

FIG. 29 is a side view illustrating a part of the tape cover included in a tape feeder according to a fifth exemplary embodiment of the present invention together with a cover tape drawing part and a guide member.

FIG. 30 is a side view illustrating a part of the tape cover included in a tape feeder according to a sixth exemplary embodiment of the present invention together with a cover tape drawing part.

### DESCRIPTION OF EMBODIMENT

### First Exemplary Embodiment

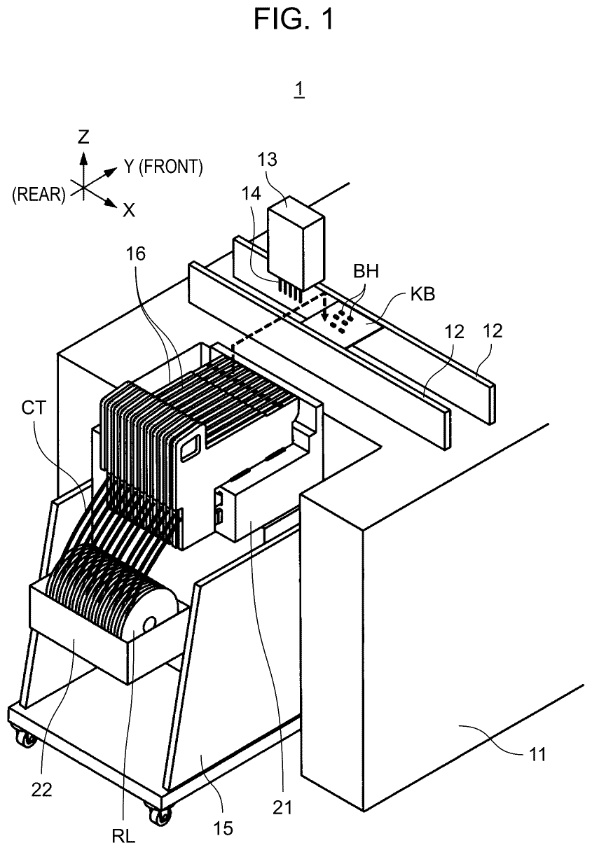

FIG. 1 illustrates component mounter 1 including a tape feeder as a component supply device according to a first exemplary embodiment of the present invention. Component mounter 1 is a device for mounting component BH on board KB. The component mounter includes board conveyance part 12 on base 11. Board conveyance part 12 conveys board KB in a horizontal direction and positions board KB at a predetermined work position. Hereinafter, for convenience of description, the conveyance directions of board KB conveyed by board conveyance part 12 are referred to as X-directions, the horizontal directions orthogonal to the X-directions are referred to as Y-directions, and the vertical directions are referred to as Z-directions. In the Y-directions, a direction facing the center side of base 11 is referred to as “front”, and a direction facing the opposite side is referred to as “rear”.

Mounting head 13 is provided above base 11. Mounting head 13 is moved in the horizontal directions by a head moving mechanism (not illustrated). Mounting head 13 includes a plurality of component retention nozzles 14 extending downward.

In FIG. 1, carriage 15 is coupled to an end of base 11 in the Y-directions. Carriage 15 includes feeder base 21 and a reel retainer 22. A plurality of tape feeders 16 are attached to feeder base 21 side by side in the X-directions.

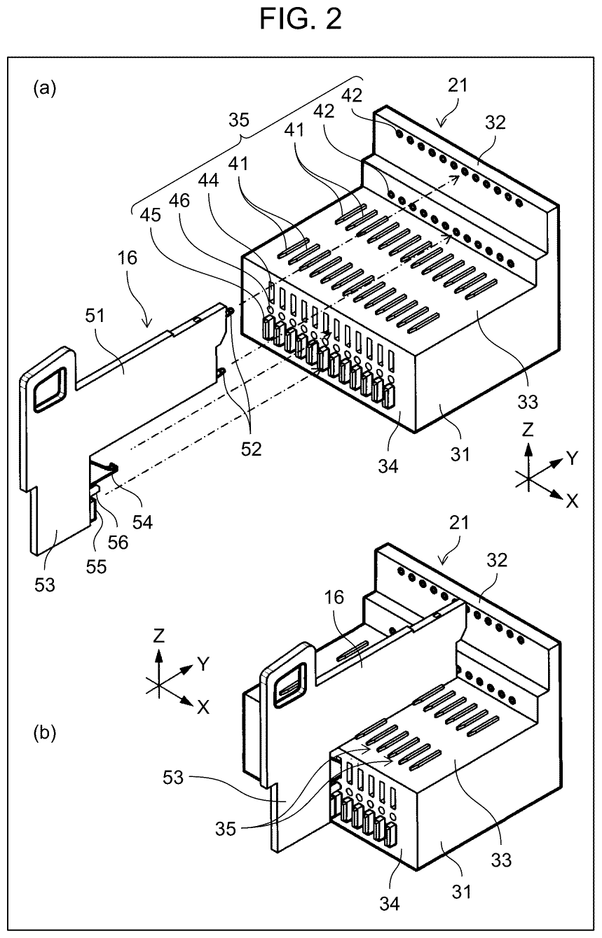

In FIGS. 2(a) and 2(b), feeder base 21 includes stand 31 having a block shape and a wall 32 provided at a front part of stand 31 and extending upward. The upper surface of stand 31 serves as a feeder support 33, and the rear surface of stand 31 serves as feeder connection surface 34.

Stand 31 is provided with attachment slots 35 in which tape feeder 16 is to be attached side by side in the X-directions. As illustrated in FIG. 2(a), single attachment slot 35 includes a pair of feeder guides 41 provided side by side in the X-directions in feeder support 33, two upper and lower positioning holes 42 that are through holes penetrating wall 32 in the thickness directions (Y-directions), attachment hole 44 provided in feeder connection surface 34, electric socket 45, and air socket 46. In the first exemplary embodiment, feeder base 21 has the plurality of attachment slots 35 arranged side by side in the X-directions like this.

Feeder guides 41 are formed of rail-shaped members arranged side by side in lateral directions (X-directions, the directions intersecting the conveyance directions of the carrier tape in a horizontal plane) and extending in the front-rear directions (Y-directions). Two upper and lower positioning holes 42 are provided side by side in the Z-directions. Attachment hole 44, electric socket 45, and air socket 46 are arranged in the Z-directions, and attachment hole 44 is located above electric socket 45. Air socket 46 is positioned between attachment hole 44 and electric socket 45.

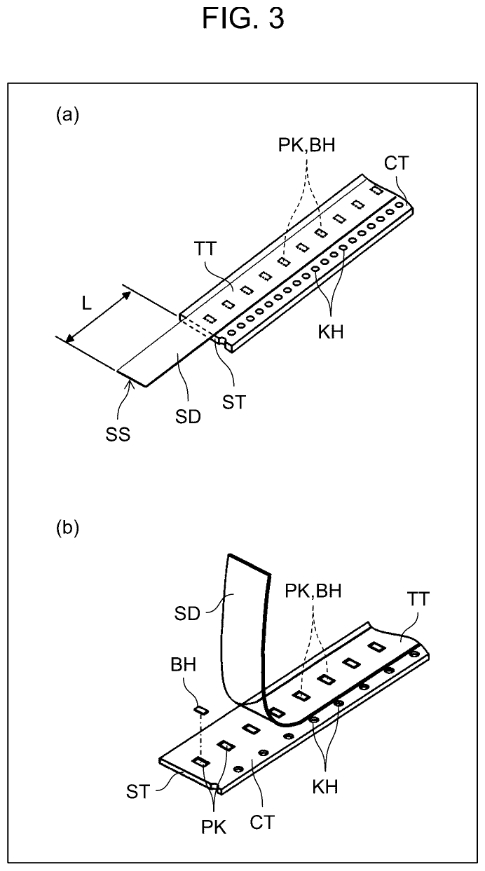

Reel retainer 22 rotatably retains reel RL around which carrier tape CT to be conveyed by tape feeder 16 is wound. As illustrated in FIGS. 3(a) and 3(b), carrier tape CT is provided with a large number of component storage pockets PK arranged in a line, and a large number of feed holes KH are provided in a line at positions parallel to the line of component storage pockets PK.

In FIGS. 3(a) and 3(b), one component BH is stored in each component storage pocket PK, and cover tape TT is attached to a position covering component storage pocket PK on the upper surface of carrier tape CT. That is, component BH is stored in carrier tape CT in a state of being covered with cover tape TT.

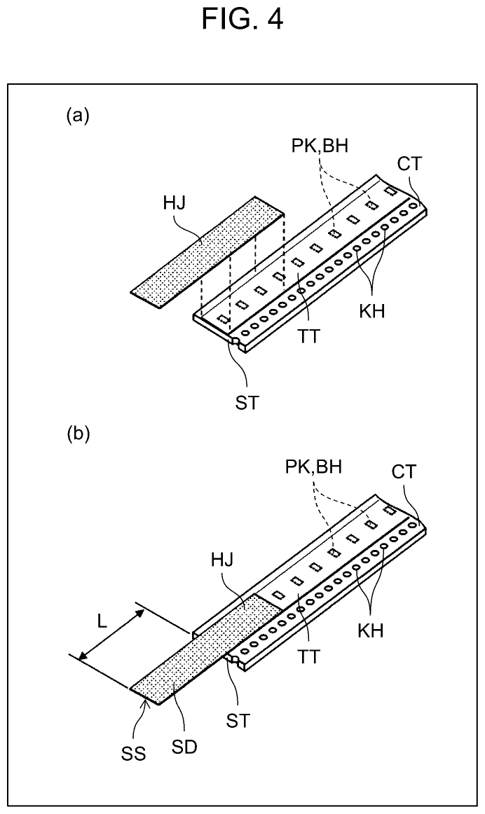

As illustrated in FIGS. 3(a) and 3(b) or FIGS. 4(a) and 4(b), cover tape TT includes lead part SD projected from tip ST of carrier tape CT. Lead part SD may have a form in which a tip part of cover tape TT is protruded from tip ST of carrier tape CT as illustrated in FIGS. 3(a) and 3(b), or may have a form in which a part of auxiliary tape HJ attached to cover tape TT is protruded from tip ST of carrier tape CT as illustrated in FIGS. 4(a) and 4(b).

In the form in which a tip of cover tape TT is protruded from tip ST of carrier tape CT, lead part SD is formed of a part (a portion having length L) of cover tape TT projected from tip ST of carrier tape CT (FIG. 3(a)). In the form using auxiliary tape HJ, lead part SD is formed of a part (a portion of length L) of auxiliary tape HJ projected from tip ST of carrier tape CT (FIG. 4(b)).

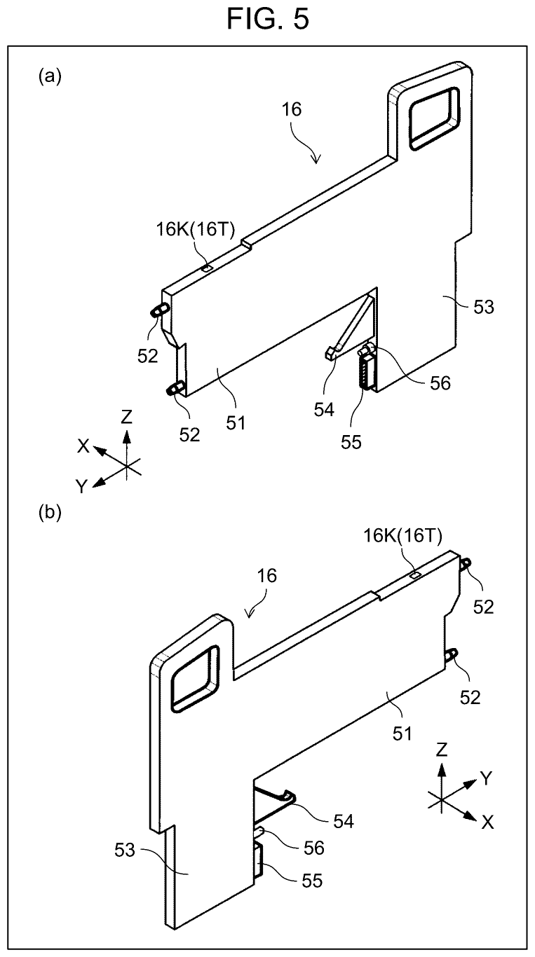

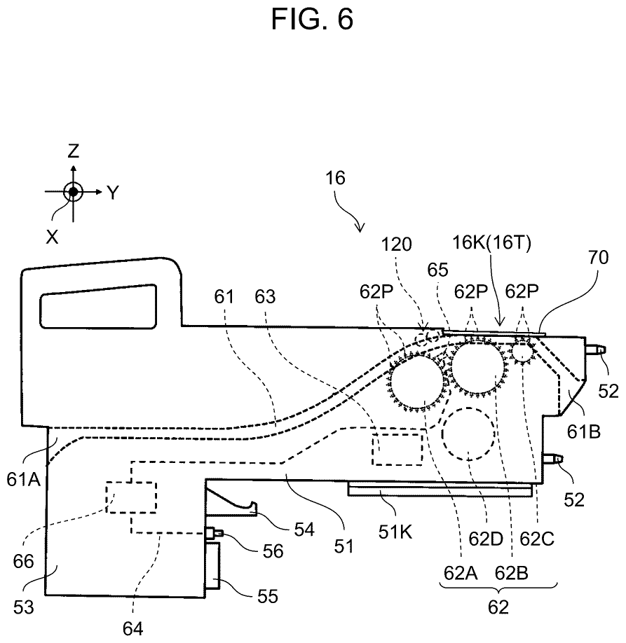

In FIGS. 5(a), 5(b), and 6, tape feeder 16 includes main body 51 detachably attached to attachment slot 35 of feeder base 21. Two positioning pins 52 protruding forward are provided at a front-end portion of main body 51.

In FIGS. 5(a), 5(b), and 6, lower extension 53 extending downward is formed at a rear portion of main body 51 of tape feeder 16. On the front side of lower extension 53, fixed part 54, connector 55, and air connector 56 are provided in a state of protruding forward.

When tape feeder 16 is attached to attachment slot 35, engaged part 51K (FIG. 6) provided at a lower portion of main body 51 is inserted between feeder guides 41 constituting attachment slot 35 (FIG. 2(a)→FIG. 2(b)). As a result, two positioning pins 52 are inserted into two upper and lower positioning holes 42, and fixed part 54 is fitted into attachment hole 44. Connector 55 is connected to electric socket 45, and air connector 56 is connected to air socket 46.

When fixed part 54 is fitted into attachment hole 44, fixed part 54 is connected to a fixture part (not illustrated) provided inside stand 31, and tape feeder 16 is fixed to stand 31. When connector 55 is connected to electric socket 45, tape feeder 16 is connected to stand 31 electrically in a signal-transmission manner. When air connector 56 is connected to air socket 46, air can be supplied from base 11 side to tape feeder 16 side through stand 31.

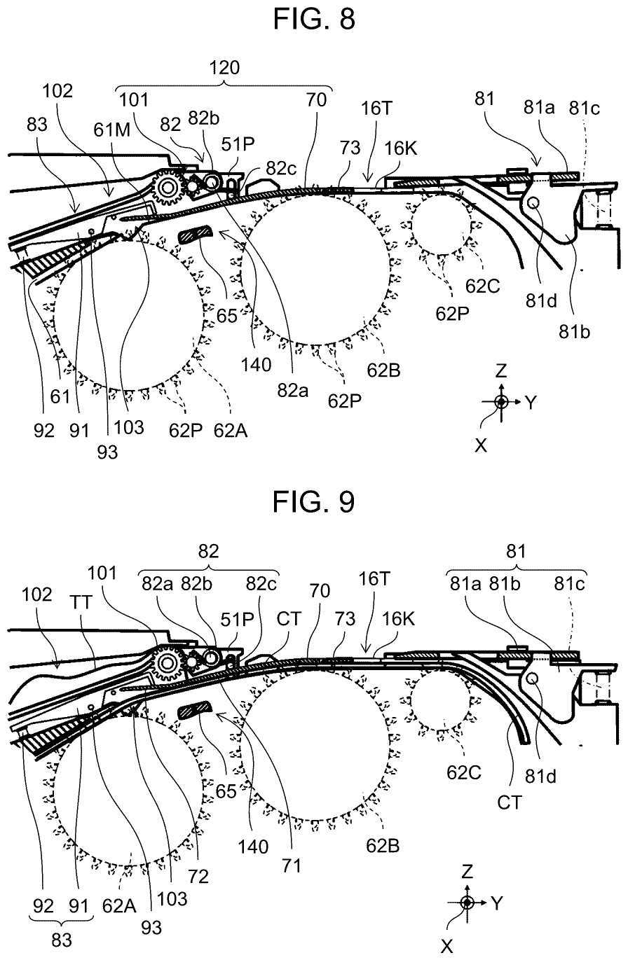

In FIG. 6, conveyance path 61 on which carrier tape CT is conveyed is provided in main body 51. Conveyance path 61 includes carrier tape introduction port 61A at a rear-end portion of main body 51 and includes carrier tape discharge port 61B at a front-end portion of main body 51. The upper surface of conveyance path 61 serves as conveyance surface 61M (see FIG. 8) for supporting and conveying the lower surface of carrier tape CT. That is, in the first exemplary embodiment, conveyance path 61 includes conveyance surface 61M that supports carrier tape CT from below.

In FIG. 6, carrier tape conveyance part 62 for conveying carrier tape CT is provided in a front upper portion of main body 51. Carrier tape conveyance part 62 includes three sprockets (introduction sprocket 62A, positioning sprocket 62B, and discharge sprocket 62C) arranged from the rear toward the front and sprocket drive motor 62D.

In FIG. 6, a plurality of feed pins 62P are provided on outer peripheral portions of introduction sprocket 62A, positioning sprocket 62B, and discharge sprocket 62C, respectively. These three sprockets are rotated in the same direction by sprocket drive motor 62D via a gear mechanism (not illustrated). The direction in which the three sprockets are rotated is the direction in which feed pin 62P located at the highest position of each sprocket moves forward. The operation of sprocket drive motor 62D is controlled by controller 63 (FIG. 6) provided in main body 51.

Carrier tape CT is drawn out from reel RL, and the tip side thereof (the side on which above-described lead part SD is formed) is inserted into conveyance path 61 from carrier tape introduction port 61A. Carrier tape CT inserted into conveyance path 61 is conveyed forward (downstream) by the three sprockets (introduction sprocket 62A, positioning sprocket 62B, and discharge sprocket 62C) that is, by carrier tape conveyance part 62, rotationally driven by sprocket drive motor 62D. At this time, carrier tape CT is delivered to introduction sprocket 62A, positioning sprocket 62B, and discharge sprocket 62C in this order.

Carrier tape CT inserted from carrier tape introduction port 61A is conveyed toward the downstream side, that is, toward carrier tape discharge port 61B by carrier tape conveyance part 62. In carrier tape CT conveyed toward the downstream side, cover tape TT is peeled off before passing through component extraction opening 16K provided in an upper front portion of main body 51, and at the time of passing through component extraction opening 16K, component BH stored in carrier tape CT in a state of being covered with cover tape TT is exposed.

Component extraction opening 16K is provided between positioning sprocket 62B and discharge sprocket 62C, and exposed components BH are intermittently positioned one after another at component extraction position 16T set inside component extraction opening 16K. As a result, mounting head 13 can suck and retain component BH positioned at component extraction opening 16K (component extraction position 16T) with component retention nozzle 14 and extract (pick up) component BH from tape feeder 16. In this manner, carrier tape conveyance part 62 conveys carrier tape CT along conveyance path 61 with lead part SD of cover tape TT leading, and positions component BH at component extraction position 16T.

In FIG. 6, air connector 56 described above provided in lower extension 53 of main body 51 is connected to air ejector 65 provided in the front upper portion of main body 51 through air pipe 64 provided in lower extension 53. Air ejection control valve 66 provided in lower extension 53 is interposed in air pipe 64.

When tape feeder 16 is attached to feeder base 21, air connector 56 is connected to air socket 46 on feeder base 21 side. By controlling air ejection control valve 66 from controller 63 in a state where air connector 56 is connected to air socket 46, the air supplied from feeder base 21 side through air pipe 64 can be ejected from air ejector 65.

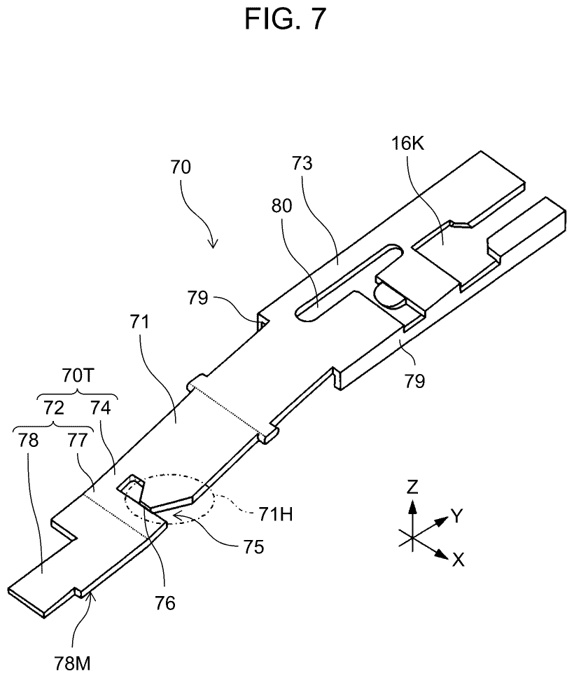

In FIG. 6, tape cover 70 illustrated in FIG. 7 is provided in the front upper portion of main body 51. Specifically, as illustrated in FIGS. 8 and 9, the tape cover is provided to cover a portion of the conveyance path 61, the portion being positioned between positioning sprocket 62B and discharge sprocket 62C from above. In the first exemplary embodiment, tape cover 70 is formed of one plate-like member and is detachable from main body 51.

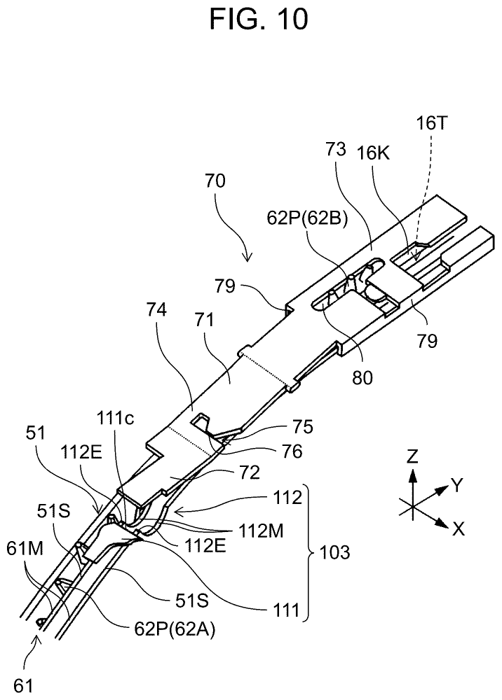

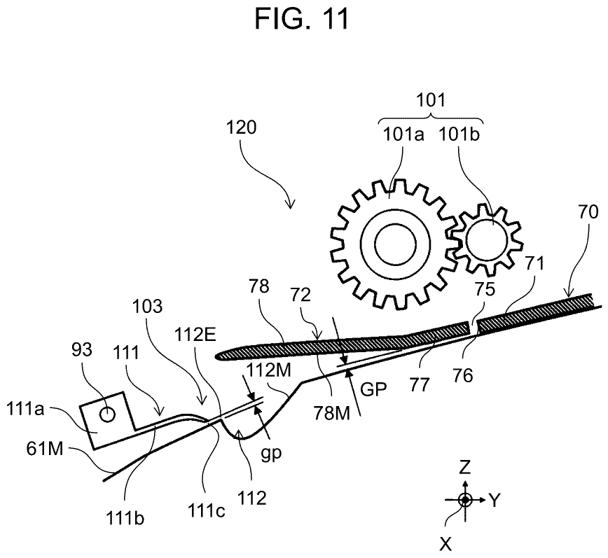

FIG. 10 illustrates a state in which tape cover 70 is attached to main body 51. As can be seen from FIG. 10, main body 51 of tape feeder 16 includes two carrier tape supports 51S that extend while spreading along the YZ plane and face each other in the X directions. An upper edge of carrier tape support 51S serves as conveyance surface 61M.

As illustrated in FIG. 10, tape cover 70 is provided on the front upper portions of two carrier tape supports 51S to cover a part of the upper edges (that is, conveyance surface 61M) of two carrier tape supports 51S from above. As described above, since conveyance surface 61M is formed of the upper edges of two carrier tape supports 51S, and both ends of carrier tape CT are supported from below by the upper edges of two carrier tape supports 51S, not only a type without a portion protruding downward (so-called paper tape type) but also an embossed type having an embossed portion protruding downward can be used as carrier tape CT.

In FIGS. 7 and 10, tape cover 70 includes first tape presser 71 constituting a central portion thereof, second tape presser 72 constituting a portion on the upstream side with respect to first tape presser 71, and third tape presser 73 constituting a portion on the downstream side with respect to first tape presser 71. First tape presser 71 and second tape presser 72 are connected by coupling part 74. Cover tape passage 75 formed of a gap between first tape presser 71 and second tape presser 72 is formed on a side (a side of tape cover 70 in the width directions, that is, a side in the X directions) of coupling part 74. Third tape presser 73 is formed with component extraction opening 16K described above (FIG. 7).

In this manner, in the first exemplary embodiment, tape cover 70 covers the upper surface of carrier tape CT conveyed by carrier tape conveyance part 62 and includes component extraction opening 16K formed at component extraction position 16T and cover tape passage 75 formed of a gap formed at a position away from component extraction opening 16K on the upstream side.

In FIG. 7, protrusion piece 71H protruding upstream is formed at an upstream end of first tape presser 71, and an edge of protrusion piece 71H (that is, an upstream edge of first tape presser 71) serves as stopper 76. As will be described later, stopper 76 functions as a part of guide 140 (FIG. 8) that guides lead part SD upward (toward the upper surface of tape cover 70) from cover tape passage 75 by stopping the advancement of lead part SD of cover tape TT included in carrier tape CT conveyed by carrier tape conveyance part 62.

As described above, second tape presser 72 is connected to the upstream side of first tape presser 71 by coupling part 74. The downstream end of second tape presser 72 has a linear shape extending in the X directions, and is positioned on the upstream side of stopper 76, which is the upstream edge of first tape presser 71, facing stopper 76 with a predetermined gap (cover tape passage 75) therebetween.

In FIG. 11, a downstream side portion of second tape presser 72 is contact part 77 extending above conveyance surface 61M in parallel with conveyance surface 61M. A portion on the upstream side with respect to contact part 77 is inclined part 78 whose height from conveyance surface 61M gradually increases toward the upstream side. The lower surface of inclined part 78 is tapered surface 78M in which the distance from conveyance surface 61M decreases from the upstream toward the downstream.

In FIG. 11, in a state where carrier tape CT is not inserted into conveyance path 61, the lower surface of second tape presser 72 does not abut on conveyance surface 61M, and a gap having size GP is formed between the lower surface of second tape presser 72 and conveyance surface 61M. Size GP of the gap is larger than the thickness of cover tape TT but smaller than the thickness of carrier tape CT.

In FIG. 7, both ends in the width directions (X directions) of third tape presser 73 serve as bent parts 79 bent downward. Since bent parts 79 are formed at both ends of third tape presser 73 in the width direction as described above, the bending rigidity in the up-down directions is increased, and the third tape presser hardly warps. Thus, carrier tape CT in the vicinity of component extraction opening 16K can be firmly pressed against conveyance surface 61M. On the other hand, since first tape presser 71 connected to the upstream side of third tape presser 73 and second tape presser 72 connected to the further upstream side of the third tape presser via coupling part 74 do not have a bent part like third tape presser 73, the first tape presser and the second tape presser can easily warp in the up-down directions.

In FIGS. 7 and 10, tape cover 70 is provided with sprocket avoiding hole 80 extending in the Y directions. Sprocket avoiding hole 80 is provided to prevent interference between feed pin 62P of positioning sprocket 62B and tape cover 70.

In FIGS. 8 and 9, tape cover 70 is biased (pressed) from above by three biasing parts (front presser 81, middle presser 82, and rear presser 83) provided at the upper front portion of main body 51. Here, front presser 81 has a function of pressing a portion of tape cover 70 on the downstream side with respect to component extraction opening 16K against carrier tape CT on conveyance surface 61M. Middle presser 82 has a function of pressing a portion between component extraction opening 16K of tape cover 70 and cover tape passage 75 against carrier tape CT on conveyance surface 61M. Rear presser 83 has a function of pressing a portion of tape cover 70 on the upstream side with respect to cover tape passage 75 against carrier tape CT on conveyance surface 61M.

In this manner, in the first exemplary embodiment, since the entire tape cover 70 is biased to conveyance surface 61M in a balanced manner by the three biasing parts (front presser 81, middle presser 82, and rear presser 83), carrier tape CT advancing on conveyance path 61 in the front upper region of main body 51 including component extraction position 16T advances while maintaining a state of being pressed against conveyance surface 61M with an appropriate pressing force. Thus, the positioning of component BH at component extraction position 16T can be accurately performed, and further, the occurrence of pickup mistakes of component BH caused by mounting head 13 can be prevented.

In FIGS. 8 and 9, front presser 81 includes presser plate 81a as a first swing lever, pedestal 81b, and first coil spring 81c. Presser plate 81a extends in the Y directions in the front upper portion of main body 51 (specifically, a region including the upper portion of discharge sprocket 62C and the vicinity of carrier tape discharge port 61B), and pedestal 81b provided at the downstream end portion is supported by main body 51 by support pin 81d extending in the X directions. First coil spring 81c is provided between pedestal 81b and main body 51, and biases pedestal 81b in a direction of pushing up the pedestal with respect to main body 51.

As illustrated in FIGS. 8 and 9, the upstream end of presser plate 81a abuts on the vicinity of the downstream end of tape cover 70 from above. Thus, the downstream side portion (third tape presser 73) of tape cover 70 is biased (pressed) downward (toward conveyance surface 61M) by first coil spring 81c via presser plate 81a.

In this manner, in the first exemplary embodiment, front presser 81 includes presser plate 81a as the first swing lever that swings about a horizontal shaft (support pin 81d) orthogonal to the conveyance directions of carrier tape CT, and first coil spring 81c that biases one end of presser plate 81a to the upper surface of tape cover 70. The lower surface of third tape presser 73 abuts on conveyance surface 61M in a state where carrier tape CT inserted into conveyance path 61 have not reached below tape cover 70 (this state is referred to as “initial state”, see FIG. 8).

In FIGS. 8 and 9, middle presser 82 includes spring retainer 82a, torsion spring 82b, and presser roller 82c. Spring retainer 82a is formed of a shaft-shaped member having both ends supported by side cover 51P provided on the side surface (YZ plane) of main body 51 so as to sandwich conveyance path 61 and extending in the X directions. Side cover 51P constitutes main body 51.

In FIGS. 8, 9, and 12, the coiled portion of torsion spring 82b is inserted into spring retainer 82a (in the X directions) to be retained by spring retainer 82a, and among the upstream extension extending upstream and the downstream extension extending downstream, the upstream extension is locked to a pin fixed to side cover 51P. Presser roller 82c extends in the X directions, and both ends thereof are supported by two side covers 51P in a movable state in the up-down directions. Presser roller 82c is rotatable about an axis along the X directions.

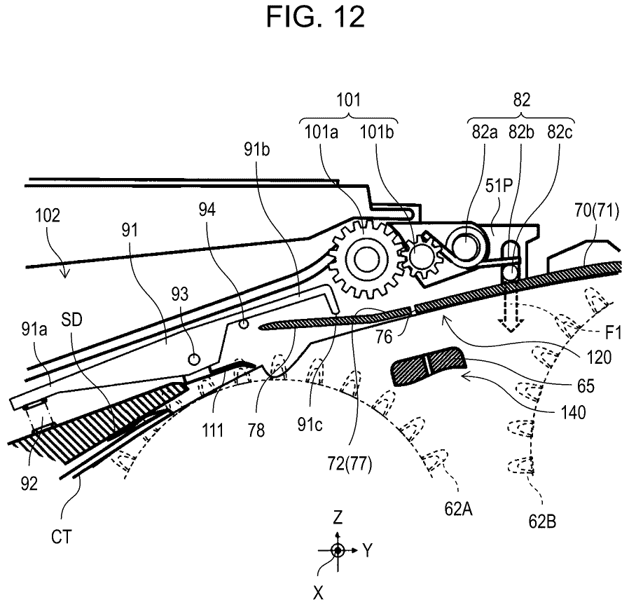

Presser roller 82c is positioned at an intermediate portion of tape cover 70 (a portion sandwiched between component extraction opening 16K and cover tape passage 75), and is biased downward by the downstream extension of torsion spring 82b. Thus, the intermediate portion (first tape presser 71) of tape cover 70 is biased (pressed) downward (to conveyance surface 61M) by torsion spring 82b via presser roller 82c (pressing force F1 illustrated in FIG. 12).

In this manner, in the first exemplary embodiment, middle presser 82 includes presser roller 82c as a roller pin that is rotatable about a horizontal axis (X axis) intersecting the conveyance directions of carrier tape CT, and torsion spring 82b as an elastic body that biases presser roller 82c to the upper surface of tape cover 70. In the initial state where carrier tape CT inserted into conveyance path 61 has not reached below tape cover 70, the lower surface of second tape presser 72 abuts on conveyance surface 61M (FIG. 12).

In FIGS. 8 and 9, rear presser 83 includes rear presser lever 91 as a second swing lever and second coil spring 92. Rear presser lever 91 extends in the Y directions in a front upper portion of main body 51 (specifically, an upper region of introduction sprocket 62A). As illustrated in FIG. 12, rear presser lever 91 includes an intermediate portion in the Y directions supported by lever swing shaft 93 extending in the X directions, and includes upstream extension 91a extending upstream from lever swing shaft 93 and downstream extension 91b extending downstream.

In FIG. 12, a tip part of downstream extension 91b is bent downward and extends, and presser lever tip part 91c that is a tip part of the bent and extended portion is positioned above second tape presser 72. Second coil spring 92 biases upstream extension 91a of rear presser lever 91 upward, that is, in a direction away from conveyance surface 61M. Thus, lever tip part 91c of rear presser lever 91 is biased downward, that is, in a direction to conveyance surface 61M.

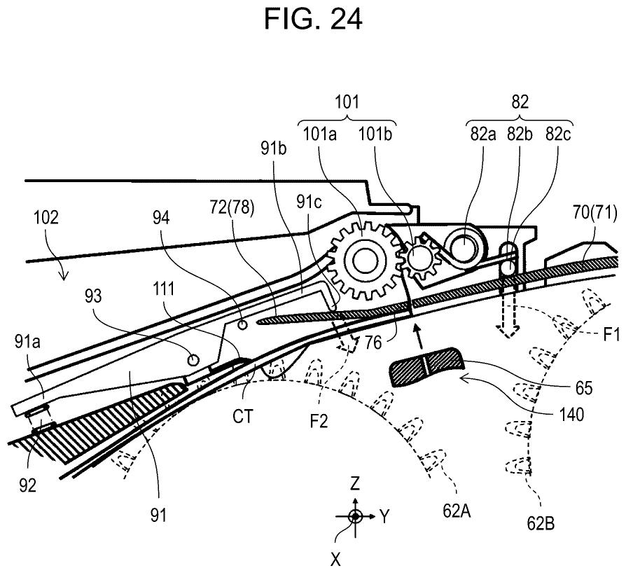

The rotation range of rear presser lever 91 is restricted by pin 94 fixed to main body 51. Thus, in the initial state where carrier tape CT has not reached below contact part 77 of second tape presser 72, lever tip part 91c is at a position separated from the upper surface of the upstream portion (second tape presser 72) of tape cover 70 by a distance smaller than the thickness dimension of carrier tape CT, and lever tip part 91c is not in contact with second tape presser 72. When carrier tape CT reaches below contact part 77 of second tape presser 72, and second tape presser 72 is lifted by carrier tape CT, second tape presser 72 abuts lever tip part 91c. As a result, second tape presser 72 is biased (pressed) downward (carrier tape CT) by second coil spring 92 via rear presser lever 91 (see also FIG. 24).

In this manner, in the first exemplary embodiment, rear presser 83 includes rear presser lever 91 as the second swing lever that swings about the horizontal axis (lever swing shaft 93) orthogonal to the conveyance directions of carrier tape CT, and second coil spring 92 that biases one end of rear presser lever 91 to the upper surface of tape cover 70. Rear presser 83 presses, together with middle presser 82, an upstream region (first tape presser 71 and second tape presser 72) located on the upstream side with respect to third tape presser 73 which is a downstream region of tape cover 70 where component extraction opening 16K is formed.

In FIGS. 8, 9, and 12, cover tape drawing part 101 is provided at a position upstream of component extraction position 16T. Specifically, the cover tape drawing part is provided at a position above tape cover 70 in main body 51. Cover tape drawing part 101 has a function of drawing upward cover tape TT peeled from carrier tape CT.

In FIGS. 11 and 12, cover tape drawing part 101 includes drive roller 101a and driven roller 101b having a smaller diameter than drive roller 101a and positioned downstream of drive roller 101a. Drive roller 101a and driven roller 101b are in contact with each other, and when drive roller 101a rotates counterclockwise in FIG. 11, driven roller 101b is rotated clockwise by drive roller 101a. Drive roller 101a is driven by a transmission gear mechanism (not illustrated) that transmits power of sprocket drive motor 62D. Thus, drive roller 101a is driven at the same timing as carrier tape conveyance part 62.

In FIGS. 8, 9, and 12, cover tape discharge path 102 is provided at a position on the upstream side with respect to cover tape drawing part 101 in main body 51. Cover tape TT drawn by cover tape drawing part 101 is discharged to cover tape discharge path 102.

In FIGS. 8, 9, and 12, straightener 103 is provided at a position on the upstream side of tape cover 70 in main body 51 (see also FIG. 11). Straightener 103 has a function of straightening lead part SD of cover tape TT of carrier tape CT inserted into conveyance path 61 from carrier tape introduction port 61A when lead part SD is bent upward or downward.

As illustrated in FIGS. 10 and 11, straightener 103 includes swing member 111 and recess 112. Straightener 103 is disposed on the upstream side with respect to component extraction position 16T, and has a function of straightening lead part SD of cover tape TT to a state of being directed downstream from tip ST of carrier tape CT along with the movement of carrier tape CT that is fed downstream and then returned upstream by carrier tape conveyance part 62.

In FIG. 11, swing member 111 includes base 111a supported by lever swing shaft 93 which is a swing shaft of rear presser lever 91, and extension 111b extending downstream from base 111a and having a tip part bent and extending downward. When swing member 111 is about to swing in a direction in which the tip side of extension 111b is lowered (clockwise direction in FIG. 11) because of its own weight, the swing member abuts on a swing restriction member (not illustrated), and its swing is restricted.

In a state where the swing of swing member 111 due to its own weight is restricted (the state illustrated in FIG. 11, referred to as “swing restriction state”), the edge of the lower end of extension 111b (swing member edge 111c) is located at a position spaced apart upward from conveyance surface 61M by a certain distance (size gp). Size gp of the fixed distance is larger than the thickness of cover tape TT and is smaller than the sum of the thickness of carrier tape CT and the thickness of cover tape TT. In the first exemplary embodiment, swing member edge 111c and conveyance surface 61M are separated from each other by the size gp. However, when there is no risk of buckling of lead part SD of cover tape TT, swing member edge 111c may abut on conveyance surface 61M.

When swing member edge 111c is pushed up by carrier tape CT from the swing restriction state illustrated in FIG. 11, swing member 111 swings in a direction in which swing member edge 111c is lifted (counterclockwise direction in FIG. 11). Then, the state in which swing member edge 111c abuts on the upper surface of carrier tape CT is maintained.

In FIGS. 10 and 11, recess 112 has curved surface 112M in which a part of conveyance surface 61M is recessed downward. As described above, since conveyance surface 61M is constituted by the upper edges of two carrier tape supports 51S located facing each other in the X directions, recess 112 (curved surface 112M) is also formed on the upper edges of these two carrier tape supports 51S (FIG. 10). Among the upstream and downstream edges of recess 112, recess edge 112E, which is the upstream edge, is located on the downstream side with respect to swing member edge 111c (FIG. 11).

Next, an operation of supplying component BH with tape feeder 16 will be described. When tape feeder 16 conveys carrier tape CT and supplies component BH to component extraction position 16T, the operator first causes lead part SD to project from the tip of carrier tape CT according to the above-described procedure, and then manually inserts tip ST of carrier tape CT into carrier tape introduction port 61A. Then, the operator pushes carrier tape CT toward the downstream side until feed hole KH at tip ST of carrier tape CT is engaged with feed pin 62P of introduction sprocket 62A.

When carrier tape CT is inserted from carrier tape introduction port 61A, feed hole KH in the vicinity of tip ST of carrier tape CT is engaged with feed pin 62P of introduction sprocket 62A, which is detected by a sensor (not illustrated). When the sensor detects that feed hole KH of carrier tape CT is engaged with feed pin 62P of introduction sprocket 62A, controller 63 operates sprocket drive motor 62D to rotate the three sprockets (introduction sprocket 62A, positioning sprocket 62B, and discharge sprocket 62C). Alternatively, the operator inserts carrier tape CT from carrier tape introduction port 61A, engages feed hole KH with feed pin 62P of introduction sprocket 62A, operates the operation switch of tape feeder 16 to operate sprocket drive motor 62D, and rotates the three sprockets. Accordingly, conveyance of carrier tape CT with carrier tape conveyance part 62 is started, and carrier tape CT advances downstream on conveyance surface 61M. At this time, tape cover 70 is still in the initial state (FIG. 12).

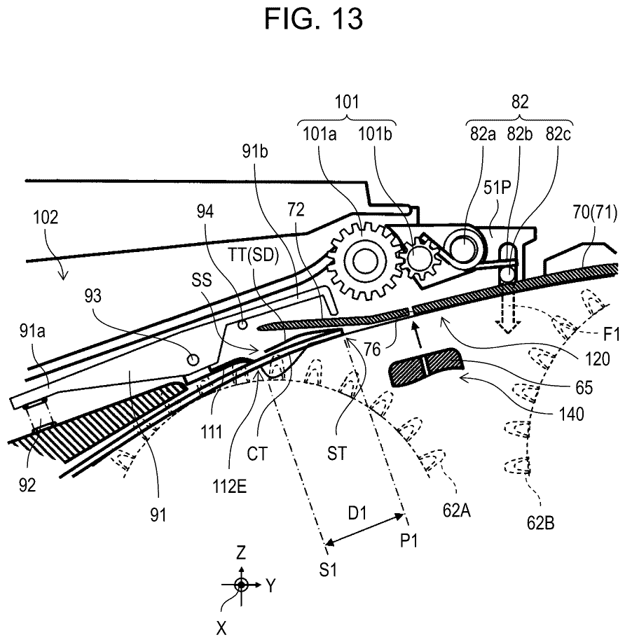

As illustrated in FIG. 13, tip ST of carrier tape CT advancing downstream on conveyance surface 61M passes below swing member edge 111c waiting at a position separated from conveyance surface 61M, and further passes through recess edge 112E. When tip ST of carrier tape CT reaches position P1 separated downstream from position S1 of recess edge 112E by predetermined distance D1 (FIG. 13), controller 63 temporarily stops the operation of sprocket drive motor 62D (that is, temporarily stops the advancement of carrier tape CT).

Here, predetermined distance D1 is a distance exceeding length L of lead part SD of cover tape TT (D1>L). Thus, when lead part SD of cover tape TT is bent upward or downward of carrier tape CT at the time point when the rotation of sprocket drive motor 62D is stopped (accordingly, the advancement of carrier tape CT is stopped), lead part tip SS (see also FIGS. 3(a) and 4(b)), which is the tip of lead part SD of cover tape TT, is located on the downstream side with respect to both swing member edge 111c and recess edge 112E (FIG. 13). When lead part SD of cover tape TT is not bent upward or downward of carrier tape CT, lead part tip SS of cover tape TT enters the space between conveyance surface 61M and lower surface of contact part 77 of second tape presser 72 (the space of the gap having size GP described above).

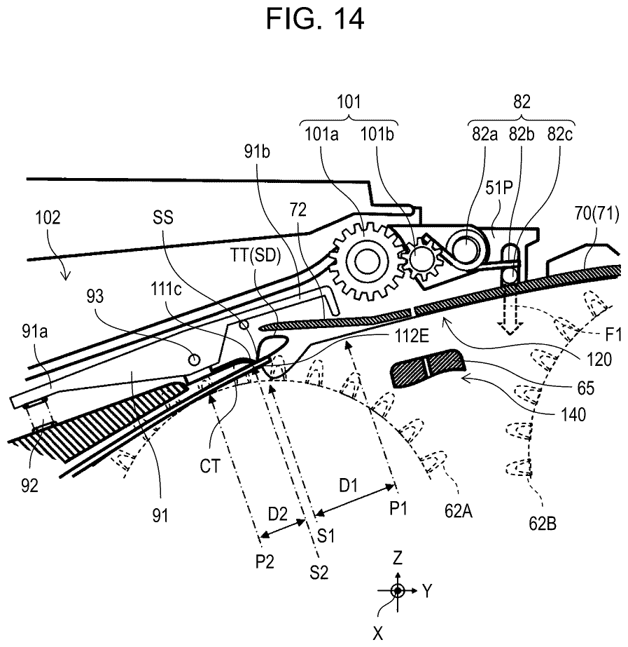

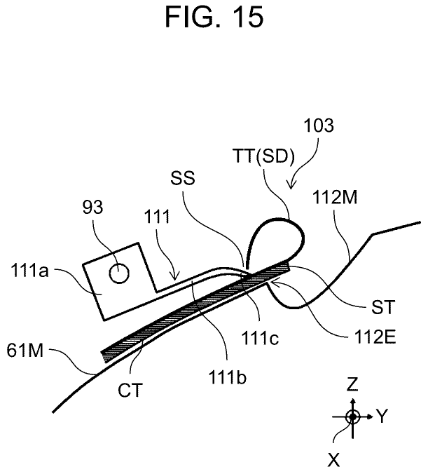

After temporarily stopping the advancement of carrier tape CT as described above, controller 63 rotates sprocket drive motor 62D in the reverse direction. As a result, carrier tape CT advances (that is, retracts) to the upstream side. When lead part SD of cover tape TT is in an upward bending state as illustrated in FIG. 13 at the time point when carrier tape CT starts to retract, lead part tip SS of cover tape TT abuts extension 111b of swing member 111 and swing member edge 111c from the downstream side (FIGS. 14 and 15).

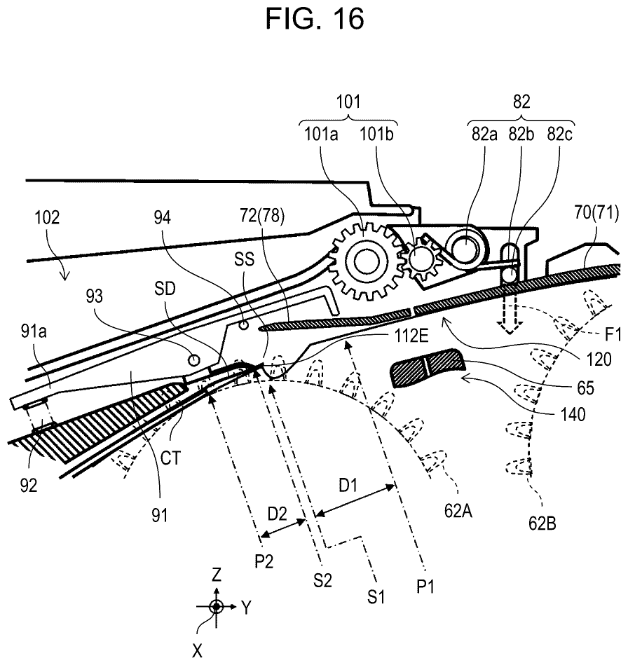

When the retracting operation of carrier tape CT is started, controller 63 stops the operation of sprocket drive motor 62D when tip ST of carrier tape CT reaches position P2 retracted downstream from position S2 of swing member edge 111c by predetermined distance D2 (FIG. 16). Here, by setting predetermined distance D2 to a distance smaller than length L of lead part SD of cover tape TT and larger than a half of the length of lead part SD (0.5L<D2<L), tip ST of carrier tape CT is located on the upstream side of swing member edge 111c when retraction operation of carrier tape CT is stopped. In this state, lead part SD of cover tape TT is released from the upward bending state, and it extends substantially straight toward the downstream side, that is, the upward bending of lead part SD of cover tape TT is straightened (FIG. 16).

In this manner, in the first exemplary embodiment, a series of operations (hereinafter, referred to as “switchback operation”) of moving tip ST of carrier tape CT forward to the downstream side with respect to the second straightening edge (here, recess edge 112E) by predetermined distance D1 (from recess edge 112E to the downstream position separated by the distance longer than length L of lead part SD), and then moving (retracting) carrier tape CT to the upstream position where tip ST is separated from the first straightening edge (swing member edge 111c) by predetermined distance D2 smaller than length L of lead part SD and larger than half of length L of lead part SD is performed. When lead part SD of cover tape TT is in the upward bending state, the state can be resolved by performing this switchback operation.

In this manner, in the first exemplary embodiment, straightener 103 includes swing member 111 disposed on the upper side of conveyance surface 61M and having swing member edge 111c as the straightening edge at the lower end. Swing member edge 111c of swing member 111 waits for the tip of carrier tape CT to advance from the upstream side at a position spaced upward from conveyance surface 61M.

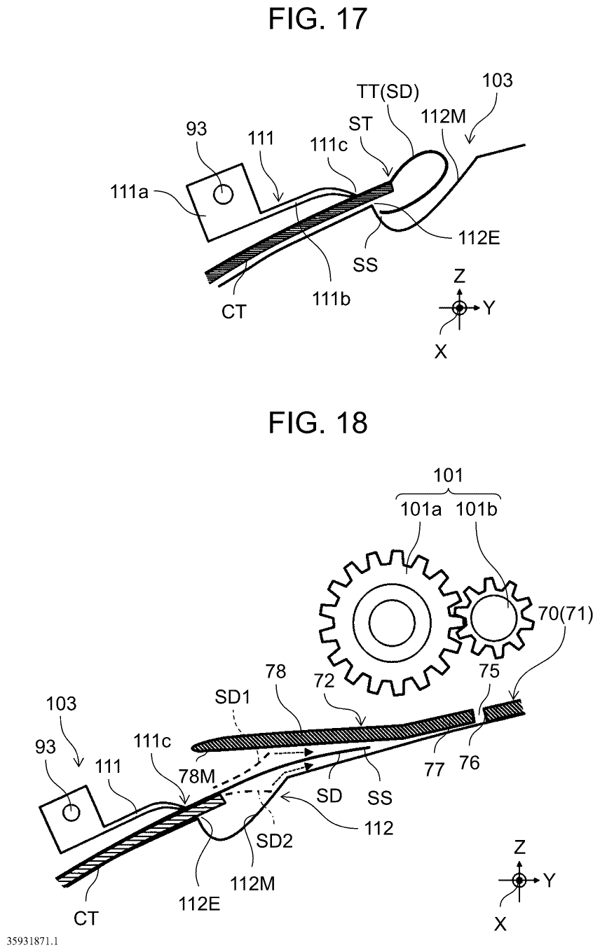

When lead part SD of cover tape TT of carrier tape CT inserted into carrier tape introduction port 61A is bent downward toward the lower side of carrier tape CT, lead part tip SS of cover tape TT is caught by the upstream edge (recess edge 112E) of recess 112 in the switchback operation (FIG. 17). Thus, in a state where the switchback operation is completed and tip ST of carrier tape CT is positioned on the upstream side with respect to swing member edge 111c (FIG. 16), the downward bending of lead part SD of cover tape TT is eliminated, and lead part SD extends substantially straight toward the downstream side, that is, the downward bending of lead part SD of cover tape TT is straightened (FIG. 16).

In this manner, in the first exemplary embodiment, recess 112 formed on the conveyance surface and recess edge 112E of the upstream edge of recess 112 serve as a part of straightener 103.

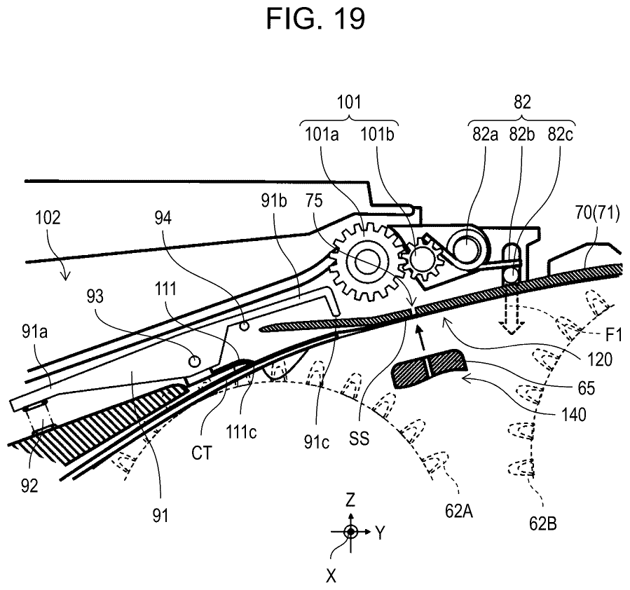

When the upward bending or the downward bending of cover tape TT is straightened by the switchback operation of carrier tape CT (FIG. 16), controller 63 operates sprocket drive motor 62D to rotate the three sprockets in the direction in which carrier tape CT advances to the downstream side. As a result, tip ST of carrier tape CT passes through swing member edge 111c toward the downstream side, and lead part tip SS of cover tape TT extending toward the downstream side enters below inclined part 78 of second tape presser 72 of tape cover 70 (FIG. 18). Further, lead part tip SS of cover tape TT enters a space between second tape presser 72 and conveyance surface 61M (a space of a gap having size GP) (FIG. 19).

Here, when lead part SD of cover tape TT that has been straightened by straightener 103 in a state of extending downstream (or lead part SD of cover tape TT that has not been bent upward or downward of carrier tape CT from the beginning when cover tape TT is inserted from carrier tape introduction port 61A) is slightly warped upward before entering the space between contact part 77 of second tape presser 72 and conveyance surface 61M (the space of the gap having size GP) (see the lead part indicated by reference sign “SD1” in FIG. 18), lead part tip SS advances to the downstream side following tapered surface 78M of second tape presser 72. Thus, lead part SD of cover tape TT once straightened by swing member edge 111c and recess edge 112E is prevented from being bent upward again. In this manner, the lower surface (tapered surface 78M) of inclined part 78 of second tape presser 72 serves as an upper bending prevention surface that prevents the upper bending of cover tape TT.

When lead part SD of cover tape TT is slightly warped downward before entering the space between second tape presser 72 and conveyance surface 61M (see the lead part indicated by reference sign “SD2” in FIG. 18), lead part tip SS follows curved surface 112M of recess 112 and advances to the downstream side. Thus, lead part SD of cover tape TT once straightened by swing member edge 111c and recess edge 112E is prevented from bending downward again. In this manner, the surface (curved surface 112M) of recess 112 serves as a downward bending prevention surface that prevents the downward bending of cover tape TT in which cover tape TT is bent toward the lower side of carrier tape CT.

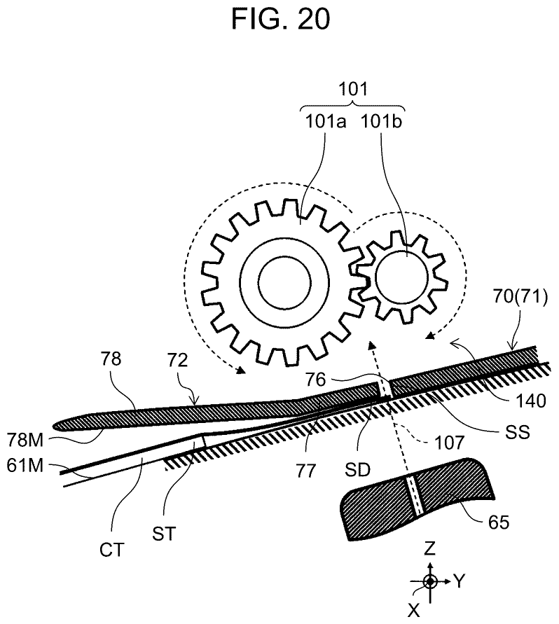

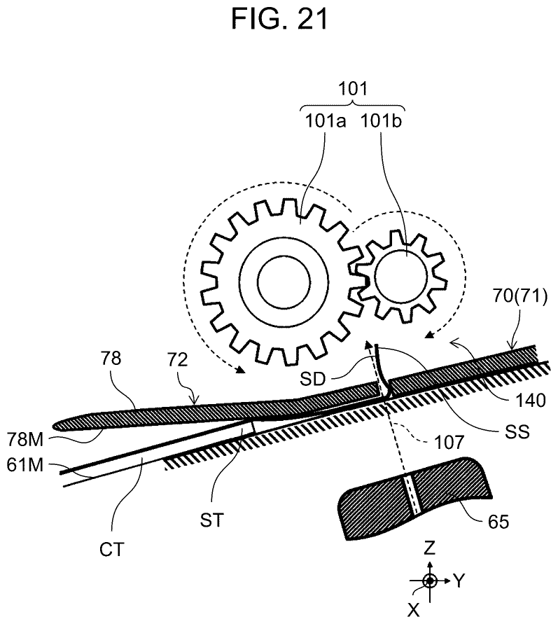

Lead part SD of cover tape TT having entered the space (the gap space having size GP) between contact part 77 of second tape presser 72 and conveyance surface 61M abuts stopper 76 abutting on conveyance surface 61M and is stopped by the stopper, whereby lead part SD is prevented from further advancing to the downstream side (FIG. 20). When the carrier tape CT is further conveyed to the downstream side, lead part tip SS of cover tape TT passes upward through cover tape passage 75 and protrudes on the upstream side of second tape presser 72 (that is, on the upstream side of tape cover 70) (FIG. 21).

In this manner, stopper 76 of first tape presser 71 has a function of stopping lead part tip SS of cover tape TT, which has advanced from the upstream side, from entering between first tape presser 71 and conveyance surface 61M in a state where first tape presser 71 abuts on conveyance surface 61M. In the first exemplary embodiment, first tape presser 71 includes stopper 76 positioned on the downstream side of second tape presser 72 and disposed on conveyance surface 61M, and it serves as a carrier tape presser that presses carrier tape CT on conveyance surface 61M.

Controller 63 controls the air ejection control valve 66 at the timing (or the timing immediately before) when lead part tip SS of cover tape TT reaches cover tape passage 75 of tape cover 70 as described above to eject air 107 upward from air ejector 65 (FIG. 21). Air ejector 65 is provided at a position where jetting air 107 passes through cover tape passage 75 from below.

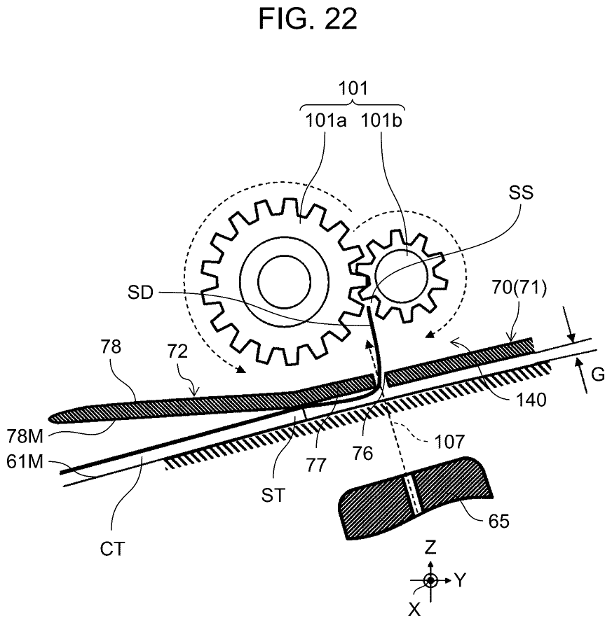

When air 107 is ejected from air ejector 65 at the timing when lead part tip SS of cover tape TT reaches cover tape passage 75, lead part tip SS of cover tape TT passes upward through cover tape passage 75 and protrudes upward from tape cover 70 while being guided by the flow of air 107 ejected from air ejector 65. As carrier tape CT advances to the downstream side, the lead part tip moves upward and reaches a position between drive roller 101a and driven roller 101b constituting cover tape drawing part 101 (FIG. 22).

In this manner, in the first exemplary embodiment, air ejector 65 serves as an auxiliary part that assists the movement of lead part SD in the direction toward cover tape drawing part 101 using the flow of air (that is, gas). In the first exemplary embodiment, first tape presser 71 as the carrier tape presser including stopper 76 and air ejector 65 as the auxiliary part constitute guide 140 that guides lead part SD toward cover tape drawing part 101.

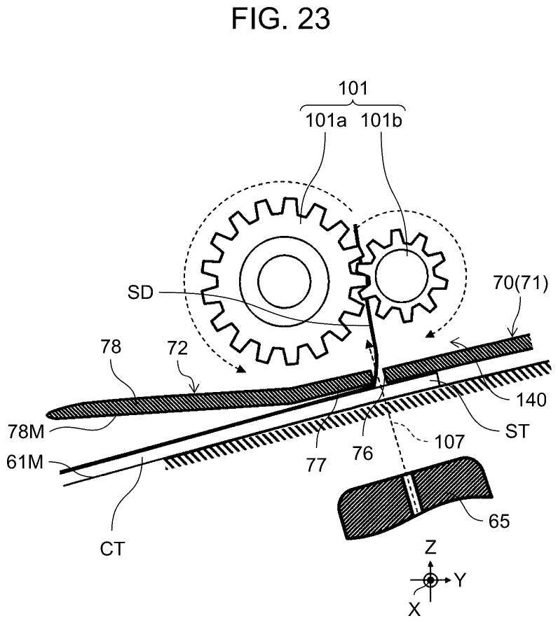

Lead part tip SS of cover tape TT that has reached a portion between drive roller 101a and driven roller 101b is caught by cover tape drawing part 101 (because of the reciprocal rotation of drive roller 101a and driven roller 101b) and drawn upward (FIG. 23).

When lead part SD of cover tape TT has passed upward through cover tape passage 75 as described above, tip ST of carrier tape CT abuts tapered surface 78M of second tape presser 72 (FIG. 21). When carrier tape CT of which tip ST abuts tapered surface 78M further advances to the downstream side, second tape presser 72 is pushed up by carrier tape CT (FIG. 21→FIG. 22).

Second tape presser 72 pushed up by carrier tape CT draws up first tape presser 71 via coupling part 74. Thus, a gap having distance G (FIG. 22) at which carrier tape CT can advance is formed between first tape presser 71 and conveyance surface 61M, and stopper 76 which is an upstream edge of first tape presser 71 also moves up from conveyance surface 61M. When the gap having distance G is formed between first tape presser 71 and conveyance surface 61M, carrier tape CT advances to the downstream side in the gap (FIG. 22→FIG. 23).

In this manner, second tape presser 72 is a contact displacement part that comes into contact with and is displaced by carrier tape CT, and coupling part 74 is a transmission part that transmits the displacement of second tape presser 72 as the contact displacement part to first tape presser 71 to displace stopper 76. Second tape presser 72 as a contact displacement part and coupling part 74 as a transmission part form height change part 70T (FIG. 7) that lifts stopper 76 upward from conveyance surface 61M.

When second tape presser 72 is pushed up by carrier tape CT as described above, inclined part 78 of second tape presser 72 abuts presser lever tip part 91c of rear presser 83 from below, and pushes up presser lever tip part 91c. As a result, second coil spring 92 of rear presser 83 is compressed by upstream extension 91a of rear presser lever 91, and biases upstream extension 91a upward as a reaction force of the compression. Thus, second tape presser 72 (inclined part 78) is biased downward by second coil spring 92 via rear presser lever 91 (pressing force F2 illustrated in FIG. 24).

In this manner, in the first exemplary embodiment, rear presser 83 is configured such that rear presser lever 91 is not in contact with tape cover 70 in a state where carrier tape CT is not present on conveyance path 61, and when the rear presser lever comes into contact with tape cover 70 (specifically, second tape presser 72) displaced upward by carrier tape CT, the rear presser presses tape cover 70 downward.

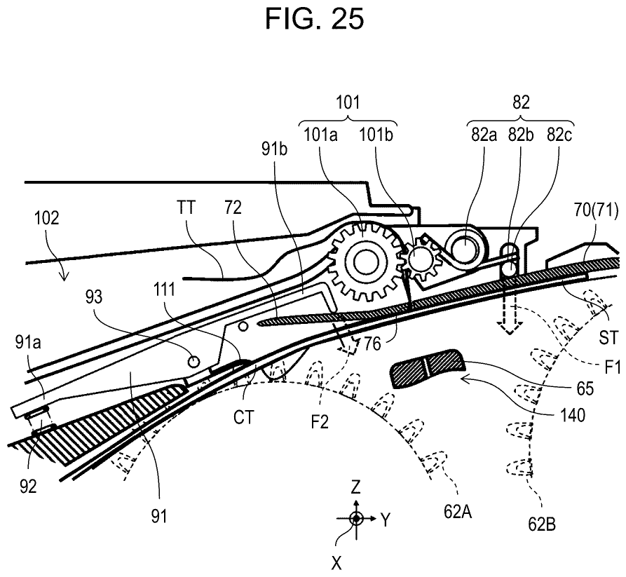

When carrier tape CT advances to the downstream side in the gap formed between the lower surface of first tape presser 71 and conveyance surface 61M, cover tape TT passing through cover tape passage 75 and extending upward is further drawn upward (into cover tape discharge path 102) by cover tape drawing part 101 (FIG. 25).

In this manner, in the first exemplary embodiment, cover tape drawing part 101 draws in cover tape TT peeled from carrier tape CT.

In the first exemplary embodiment, tape cover 70 and cover tape drawing part 101 constitute cover tape peeling part 120 (FIG. 8) (see also FIGS. 6 and 11). Here, cover tape peeling part 120 refers to a functional part that is disposed downstream of straightener 103 and upstream of component extraction position 16T, and peels cover tape TT from the upper surface of carrier tape CT fed downstream by carrier tape conveyance part 62 by catching and drawing in lead part SD of cover tape TT extended downstream from tip ST of carrier tape CT.

Carrier tape CT from which cover tape TT is peeled off by cover tape peeling part 120 is conveyed downstream on conveyance path 61 by carrier tape conveyance part 62, and first component storage pocket PK in carrier tape CT is positioned at component extraction position 16T. The carrier tape CT positioning step thus ends. Carrier tape conveyance part 62 executes the operation (carrier tape CT positioning step) of positioning first component storage pocket PK of carrier tape CT from position P2 to component extraction position 16T without stopping.

In carrier tape CT, cover tape TT is peeled off by cover tape peeling part 120 in the process of positioning carrier tape CT. Thereafter, a pitch feeding is performed by carrier tape conveyance part 62 along with the operation in which mounting head 13 included in component mounter 1 sucks and extracts component BH (pickup operation), and component storage pocket PK is sequentially positioned at component extraction position 16T (carrier tape positioning operation).

In this manner, in the first exemplary embodiment, tape feeder 16 serving as a component supply device is configured to peel off cover tape TT having lead part SD projected from the tip of carrier tape CT from carrier tape CT, expose component BH stored on carrier tape CT in a state of being covered with cover tape TT, convey exposed component BH to component extraction position 16T, and supply component BH to component mounter 1.

When component mounter 1 including tape feeder 16 having the above configuration performs a component mounting work of mounting component BH on board KB, first, board KB supplied from the outside of component mounter 1 is carried in by board conveyance part 12 and positioned at a predetermined work position. When board KB is positioned at the work position, each tape feeder 16 supplies component BH to component extraction opening 16K, and mounting head 13 retains and extracts component BH from component extraction position 16T of tape feeder 16 with component retention nozzle 14. Mounting head 13 that has extracted component BH from component extraction position 16T of tape feeder 16 moves above board KB and mounts component BH at a target component mounting position determined on board KB. When all components BH to be mounted on board KB are mounted, board conveyance part 12 conveys board KB to the outside of component mounter 1. The component mounting work per single board KB thus ends.

As described above, tape feeder 16 according to the first exemplary embodiment conveys carrier tape CT along conveyance path 61 with lead part SD of cover tape TT leading, and returns carrier tape CT fed downstream to the upstream side, thus the bent state of lead part SD can be straightened by straightener 103. Thus, even when lead part SD of cover tape TT is bent, lead part SD can be reliably caught by cover tape drawing part 101.

Tape feeder 16 according to the first exemplary embodiment includes guide 140 that guides lead part SD toward cover tape drawing part 101, and lead part SD of cover tape TT is stopped by stopper 76 and guided. Thus, lead part SD of cover tape TT can be reliably guided and caught by cover tape drawing part 101. After lead part SD of cover tape TT is caught by cover tape drawing part 101, stopper 76 is lifted upward by height change part 70T. Thus, carrier tape CT can advance on conveyance path 61 without being caught by stopper 76, and the conveyance of carrier tape CT is not blocked. Guide 140 in tape feeder 16 according to the first exemplary embodiment includes a carrier tape presser (first tape presser 72) that presses carrier tape CT on conveyance surface 61M downstream of the contact displacement part (second tape presser 71).

In tape feeder 16 according to the first exemplary embodiment, a portion of tape cover 70 including component extraction opening 16K and cover tape passage 75 on the downstream side with respect to component extraction opening 16K is pressed by front presser 81, a portion sandwiched between component extraction opening 16K and cover tape passage 75 is pressed by middle presser 82, a portion on the upstream side with respect to cover tape passage 75 is pressed by rear presser 83, and entire tape cover 70 is pressed against conveyance path 61 with an appropriate balance. Thus, carrier tape CT can be stably conveyed in the region including the vicinity of component extraction position 16T, and the extraction accuracy of component BH can be improved.

### Second Exemplary Embodiment

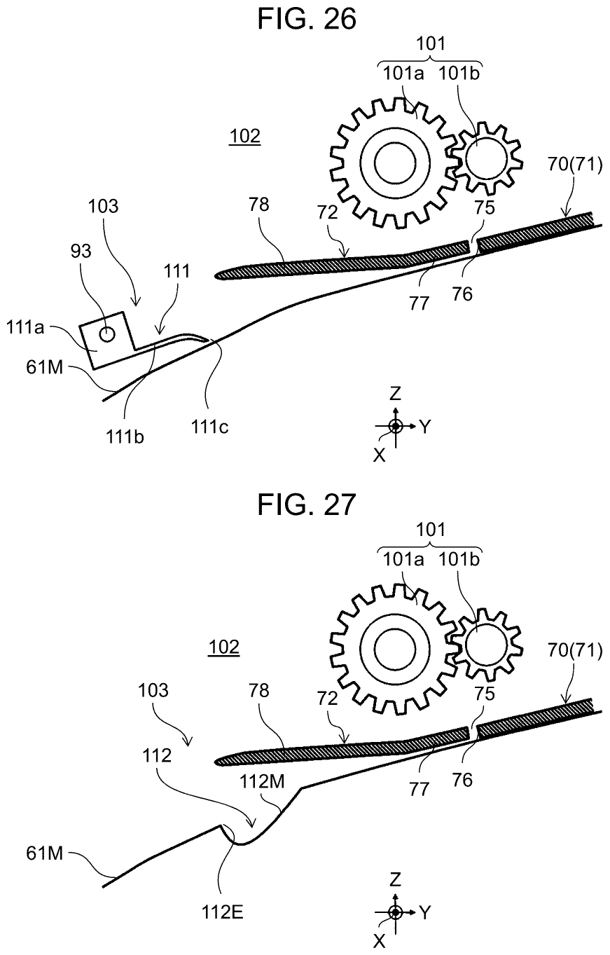

FIG. 26 illustrates a part of a tape feeder according to a second exemplary embodiment. The tape feeder according to the second exemplary embodiment is the same as tape feeder 16 according to the first exemplary embodiment except that the straightening edge is only the straightening edge facing the upper surface of carrier tape CT (swing member edge 111c in the first exemplary embodiment).

The second exemplary embodiment is different from the first exemplary embodiment in that straightener 103 does not include recess 112. This configuration can be adopted when lead part SD of cover tape TT of carrier tape CT inserted from carrier tape introduction port 61A cannot bend downward, that is, when lead part SD of cover tape TT is bent upward in advance when carrier tape CT is inserted from carrier tape introduction port 61A, that is, when carrier tape CT is inserted into carrier tape introduction port 61A in a state where lead part SD is bent upward. In the second exemplary embodiment as well, since straightener 103 includes a straightening edge, the same effect as in the case of tape feeder 16 in the first exemplary embodiment can be obtained.

### Third Exemplary Embodiment

FIG. 27 illustrates a part of a tape feeder according to a third exemplary embodiment. The tape feeder according to the third exemplary embodiment is the same as tape feeder 16 according to the first exemplary embodiment except that the straightening edge is only the edge of recess 112 formed on conveyance surface 61M.

The third exemplary embodiment is different from the first exemplary embodiment in that straightener 103 does not include swing member 111. This configuration can be adopted when lead part SD of cover tape TT of carrier tape CT inserted from carrier tape introduction port 61A cannot bend upward, that is, when lead part SD of cover tape TT is bent downward in advance when carrier tape CT is inserted from carrier tape introduction port 61A, that is, when carrier tape CT is inserted into carrier tape introduction port 61A in a state where lead part SD is bent downward. In the third exemplary embodiment as well, since straightener 103 includes a straightening edge, the same effect as in the case of tape feeder 16 in the first exemplary embodiment can be obtained.

### Fourth Exemplary Embodiment

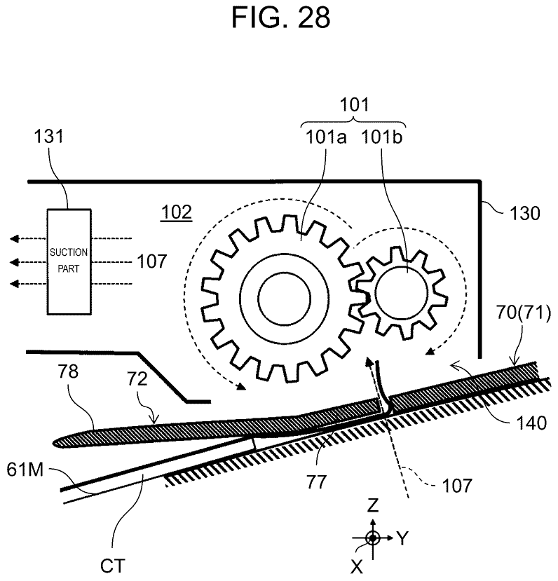

FIG. 28 illustrates a part of a tape feeder according to a fourth exemplary embodiment. The tape feeder according to the fourth exemplary embodiment is the same as tape feeder 16 according to the first exemplary embodiment except that the tape feeder according to the fourth exemplary embodiment does not include air ejector 65 in the first exemplary embodiment, and instead, duct 130 that covers cover tape discharge path 102 and suction part 131 that sucks air 107 in duct 130 are provided. Guide 140 of the fourth exemplary embodiment includes first tape presser 71 and suction part 131.

In the fourth exemplary embodiment, air 107 in duct 130 is sucked by suction part 131 provided on the upper side of conveyance surface 61M. Thus, lead part SD of cover tape TT is reliably drawn into cover tape drawing part 101 through cover tape passage 75 without air ejector 65 in the first exemplary embodiment. That is, in the fourth exemplary embodiment, similarly to air ejector 65 described above, suction part 131 serves as an auxiliary part that assists the movement of lead part SD in the direction toward cover tape drawing part 101 using the flow of gas. Similarly to air ejector 65, suction part 131 also exhibits a function of guiding lead part tip SS of cover tape TT toward cover tape drawing part 101. Thus, the same effect as in the case of tape feeder 16 in the first exemplary embodiment can be obtained also in the fourth exemplary embodiment.

### Fifth Exemplary Embodiment

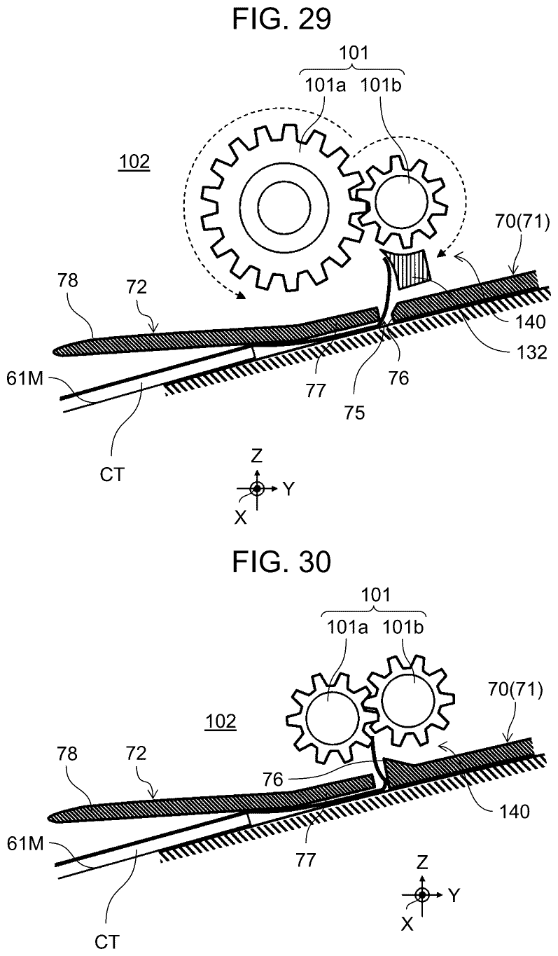

FIG. 29 illustrates a part of a tape feeder according to a fifth exemplary embodiment. The tape feeder according to the fifth exemplary embodiment is the same as tape feeder 16 according to the first exemplary embodiment except that the tape feeder according to the fifth exemplary embodiment does not include air ejector 65 in the first exemplary embodiment, and instead, guide member 132 is provided on the downstream side above cover tape passage 75. The shape of stopper 76 is changed such that it does not stop the advancement of lead part SD of cover tape TT but facilitates lead part SD to move upward from cover tape passage 75. Guide 140 of the fifth exemplary embodiment includes first tape presser 71 and guide member 132.

In the fifth exemplary embodiment, lead part SD abutting on stopper 76 changes its moving direction upward, and protrudes upward from tape cover 70 through cover tape passage 75. Lead part SD of cover tape TT moved upward of tape cover 70 is guided toward cover tape drawing part 101 by guide member 132. Thus, lead part SD of cover tape TT is reliably caught by cover tape drawing part 101, and the same effect as in the case of tape feeder 16 according to the first exemplary embodiment can be obtained.

### Sixth Exemplary Embodiment

FIG. 30 illustrates a part of a tape feeder according to a sixth exemplary embodiment. The tape feeder according to the sixth exemplary embodiment is the same as tape feeder 16 according to the first exemplary embodiment except that the tape feeder according to the sixth exemplary embodiment does not include air ejector 65, and the shape of stopper 76 of tape cover 70 (in particular, the height from conveyance surface 61M), the size and arrangement of drive roller 101a and driven roller 101b constituting cover tape drawing part 101, and the like are different from those of the first exemplary embodiment. The shape of stopper 76 is changed such that it does not stop the advancement of lead part SD of cover tape TT but facilitates lead part SD to move upward from cover tape passage 75. Guide 140 of the sixth exemplary embodiment is formed only of first tape presser 71.

In the sixth exemplary embodiment, lead part SD of cover tape TT protruding upward from tape cover 70 through cover tape passage 75 can be guided to cover tape drawing part 101 without the need for the auxiliary part (air ejector 65, suction part 131, guide member 132, and the like). Thus, in the sixth exemplary embodiment as well, the same effect as in the case of tape feeder 16 in the first exemplary embodiment can be obtained.

As described above, the component supply device (tape feeder 16) according to the first to sixth exemplary embodiments conveys carrier tape CT along conveyance path 61 with lead part SD of cover tape TT leading, and returns carrier tape CT fed downstream to the upstream side, thus the bent state of lead part SD can be straightened by straightener 103. Thus, even when lead part SD of cover tape TT is bent, lead part SD can be reliably caught by cover tape drawing part 101.

Although the exemplary embodiments of the present invention have been described in the foregoing, the present invention is not limited to the above exemplary embodiments, and various modifications and the like can be made. For example, as in the first, second, and fourth to sixth exemplary embodiments described above, when swing member 111 is in the swing restriction state, the advancement of carrier tape CT may be waited with swing member edge 111c abutting on conveyance surface 61M instead of the configuration in which the advancement of carrier tape CT is waited with swing member edge 111c separated from conveyance path 61. In this case, conveyance surface 61M may be configured to function as a swing restriction member in the first exemplary embodiment.

### INDUSTRIAL APPLICABILITY

Provided is a component supply device that can reliably catch a lead part of a cover tape into a cover tape drawing part even when the lead part of the cover tape is bent.

### REFERENCE MARKS IN THE DRAWINGS

1 component mounter
16 tape feeder (component supply device)
51 main body
61 conveyance path
61M conveyance surface
62 carrier tape conveyance part
62A introduction sprocket
62B positioning sprocket
62C discharge sprocket
65 air ejector
70 tape cover
71 first tape presser
72 second tape presser
73 third tape presser
74 coupling part
75 cover tape passage
76 stopper
77 contact part
78 inclined part
78M tapered surface (upper bending prevention surface)
81 front presser
81a presser plate
81c first coil spring
82 middle presser
82a spring retainer
82b torsion spring
82c presser roller
83 rear presser
91 rear presser lever
92 second coil spring
101 cover tape drawing part
103 straightener
111 swing member
111c swing member edge (straightening edge)
112 recess
112M curved surface (downward bending prevention surface)
112E recess edge (straightening edge)
120 cover tape peeling part
CT carrier tape
ST tip
TT cover tape
SD lead part
SS lead part tip
BH component
KB board

1. A component supply device that peels off a cover tape including a lead part projected from a tip of a carrier tape from the carrier tape, exposes a component stored in the carrier tape in a state of being covered with the cover tape, conveys the component that has been exposed to a component extraction position, and supplies the component to a component mounter, the component supply device comprising:
a conveyance path including a conveyance surface that supports the carrier tape from below;
a carrier tape conveyance part that conveys the carrier tape along the conveyance path with the lead part leading, to position the component at a component extraction position;
a straightener that is disposed on an upstream side with respect to the component extraction position and straightens the lead part to a state of being directed downstream from the tip of the carrier tape along with movement of the carrier tape that has been sent downstream and then returned upstream by the carrier tape conveyance part; and
a cover tape peeling part that is disposed on a downstream side of the straightener and on the upstream side with respect to the component extraction position and peels off the cover tape from an upper surface of the carrier tape being sent downstream by the carrier tape conveyance part by catching and drawing the lead part extended downstream from the tip of the carrier tape.

2. The component supply device according to claim 1, wherein the straightener includes a straightening edge facing an upper surface or a lower surface of the carrier tape.

3. The component supply device according to claim 1, wherein the straightener includes a first straightening edge facing an upper surface of the carrier tape and a second straightening edge facing a lower surface of the carrier tape.

4. The component supply device according to claim 3, wherein the straightener includes a swing member disposed on an upper side of the conveyance surface and having the first straightening edge at a lower end.

5. The component supply device according to claim 4, wherein the first straightening edge waits at a position separated from the conveyance surface.

6. The component supply device according to claim 3, the component supply device further comprising an inclined part disposed on an upper side of the conveyance surface and having a tapered surface in which a distance from the conveyance surface decreases from an upstream side to a downstream side,
wherein the tapered surface is an upward bending prevention surface that prevents upward bending of the cover tape.

7. The component supply device according to claim 3, wherein
the straightener further includes a recess formed in the conveyance surface, and
the second straightening edge includes an upstream edge of the recess.

8. The component supply device according to claim 7, wherein a surface of the recess is a downward bending prevention surface that prevents downward bending of the cover tape.

9. The component supply device according to claim 2, wherein
the tip of the carrier tape is conveyed downstream from the straightening edge to a position separated by a distance larger than a length of the lead part, and
after the conveyance, the tip of the carrier tape is moved to an upstream side of the straightening edge to a position separated by a distance smaller than the length of the lead part and larger than a half of the length of the lead part.
